(19) United States
(12) Patent Application Publication
(10) Pub. No.: US 2014/0355215 A1
(43) Pub. Date: Dec. 4, 2014

(54) Embedded Heat Slug to Enhance Substrate Thermal Conductivity

(71) Applicant: Dialog Semiconductor GmbH, Kirchheim/Teck-Nabern (DE)

(72) Inventors: Baltazar Canete, Waiblingen (DE); Melvin Martin, Stuttgart (DE); Ian Kent, Calne (GB)

(21) Appl. No.: 13/908,209

(22) Filed: Jun. 3, 2013

(30) Foreign Application Priority Data
May 31, 2013 (EP) 13368016.5

(51) Int. Cl. H05K 7/20; H05K 3/30

(52) U.S. Cl. CPC H05K 7/20436; H05K 3/30
USPC 361/720; 29/831

(57) ABSTRACT

An electronic package is fabricated wherein a substrate is provided having three or more layers. A heat slug is embedded completely within the substrate. A die is attached above the substrate. Thermal paths to the heat slug are linked through the ground signal interconnects (traces, vias and planes).

### (1) TECHNICAL FIELD

This disclosure is related to electronic packages, and more particularly, to improved heat dissipation in substrate-based electronic packages.

### (2) BACKGROUND

Electronic packaging technology demands smaller and more complex packages. A heat slug, or heat spreader, is a rectangular metal plate used to dissipate heat away from electronic devices. Typically, heat slugs are mounted on top of the package or die. This adds to manufacturing cost. If a heat slug is not used, junction temperature will increase, eventually leading to system failure.

U.S. Pat. No. 5,642,261 (Bond et al), U.S. Pat. No. 5,285,352 (Pastore et al), and U.S. Pat. No. 6,282,094 (Lo et al) disclose heat slugs, but in these disclosures, the heat slug is packaged completely differently from the present disclosure.

### SUMMARY

It is the primary objective of the present disclosure to embed a heat slug within a substrate.

Another objective of the present disclosure is to provide a method to improve the heat flow out of electronic devices in a package.

A further objective is to provide an electronic package having an embedded heat slug.

A yet further objective is to provide an electronic package in which a heat slug is embedded in the substrate dielectric layer and in which the heat slug is not exposed on its top or bottom side.

In accordance with the objectives of the present disclosure, a method of fabricating an electronic package is achieved. A substrate is provided having three or more layers, comprising a dielectric layer and a metal layer within the dielectric layer thermally connected to at least one metal layer on top of the dielectric layer and to at least one metal layer on bottom of the dielectric layer. A heat slug is embedded completely within the dielectric layer. A die is attached above the substrate. Thermal paths to the heat slug are linked through all of the metal layers.

Also in accordance with the objectives of the present disclosure, a method of fabricating an electronic package is achieved. A substrate is provided having three or more layers, comprising a dielectric layer and a metal layer within the dielectric layer thermally connected to at least one metal layer on top of the dielectric layer and to at least one metal layer on bottom of the dielectric layer wherein the thermally connected metal layers form ground signal interconnects. A heat slug is embedded completely within the dielectric layer. A die is attached above the substrate wherein the die has no direct connection to the heat slug. Thermal paths are linked to the heat slug through the ground signal interconnects.

Also in accordance with the objectives of the present disclosure, an electronic package is achieved. The electronic package comprises a substrate having three or more metal layers, comprising a dielectric core layer and a metal layer within the dielectric core layer thermally connected to at least one metal layer on top of the dielectric core layer and to at least one metal layer on bottom of the dielectric core layer. A die is attached above the substrate and a heat slug is embedded within the dielectric layer wherein the heat slug has no direct contact to the die and wherein the heat slug is thermally connected to each of the metal layers.

### BRIEF DESCRIPTION OF THE DRAWINGS

In the accompanying drawings forming a material part of this description, there is shown:

FIGS. 1-7 are cross-sectional representations of a method according to a first preferred embodiment of the present disclosure, using a three-layer substrate.

FIG. 8 is an exploded view of the layers in FIG. 7.

FIGS. 9-13 are cross-sectional representations of a second preferred embodiment of the present disclosure, using an eight-layer substrate.

### DETAILED DESCRIPTION

The present disclosure provides an electronic package having improved heat flow as well as increased miniaturization. Embedding a heat slug within a substrate minimizes junction temperature increases without increasing the assembly process manufacturing cost. As far as the assembly process is concerned, mounting the heat slug on top of the die will increase the manufacturing cost since it will incur additional assembly process and will increase through-put time. However, substrate manufacturing is not part of the assembly process and as a result, will not affect assembly cost since the heat slug is already embedded inside the substrate prior to assembly manufacturing.

In the process of the present disclosure, a heat slug will be embedded in a substrate underneath the die, just below the die attach glue. This will enable the heat flow to be concentrated to the substrate. Other advantages of this concept are:
Better thermal flux and faster heat dissipation
Lower thermal resistance
Flexible substrate routing
Thinner package

This method should be applicable to all packages using a BT (Bismaleimide Triazine) rigid laminate substrate. For example, a ball grid array (BGA) package with wire bonds is shown. However, it is also possible to embed a heat slug in other packages, such as Flip Chip Chip Scale Package (FC-CSP), Land Grid Arrays (LGA), or System in Package (SIP).

Referring now more particularly to FIGS. 1-7, a preferred method of embedding a heat slug within a substrate will be described. FIG. 1 illustrates a core substrate 10. A standard substrate starts from a copper clad laminate with two metal (copper) layers separated by a dielectric core material. For example, this substrate includes a dielectric core material 10 and top and bottom copper layers. This will be built up by additional metal layers on top and/or bottom with prepregnated dielectric material for every stack/layer. The core layer will be cut to create a cavity area such that the heat slug can be placed inside. This cavity area may be drilled such as by laser or mechanical drilling.

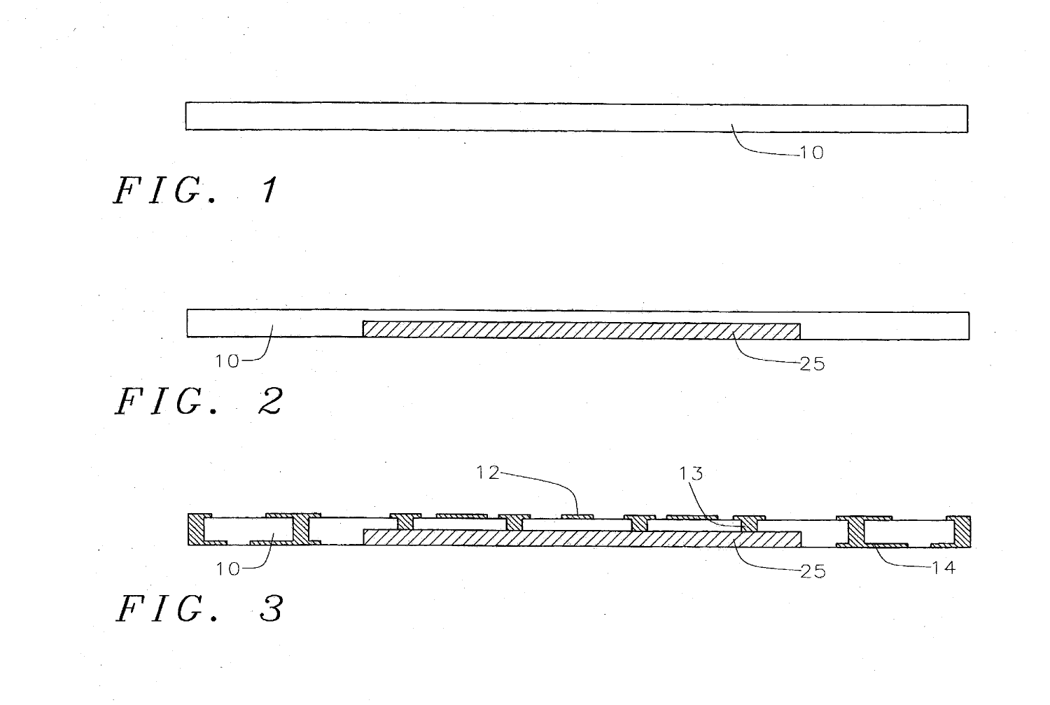

FIG. 2 illustrates the heat slug 25 embedded in the cavity in the substrate core layer. In this embodiment, the cavity does not extend the entire depth of the core substrate.

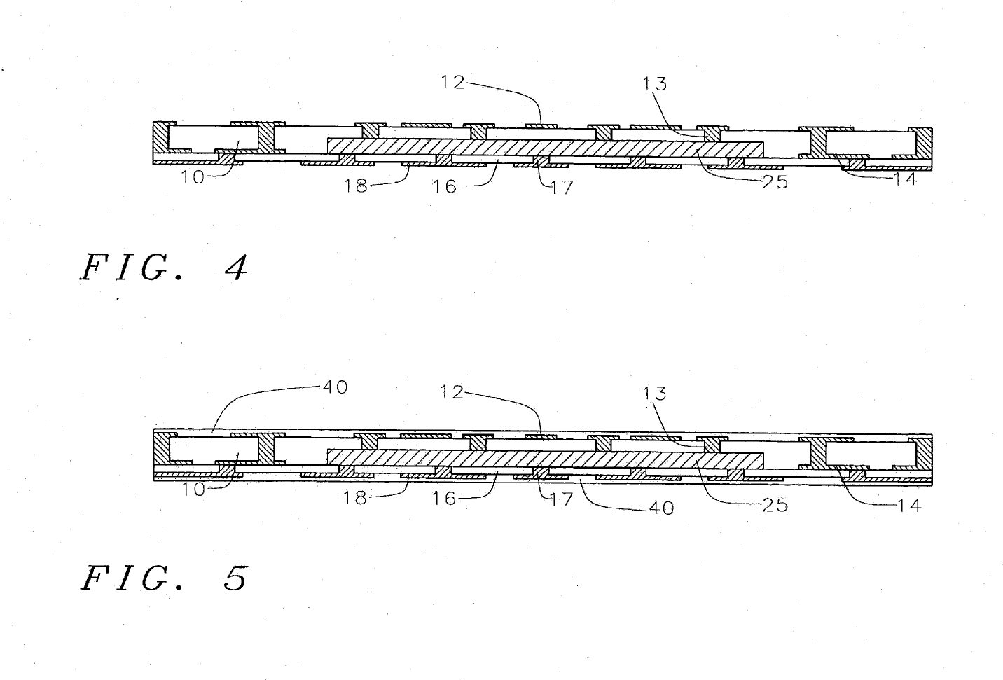

Now, a first metal layer 12 and second metal layer 14 are formed on the top and bottom of the core material 10, respectively. Thermal via connections 13 are formed in the first metal layer to connect to the heat slug 25 and to connect metal 12 and metal 14, as shown in FIG. 3. Succeeding build up layers will then be laminated on top and/or bottom of the core substrate. FIG. 4 shows a first build-up substrate comprising dielectric prepregnated material 16 laminated on the bottom of the core substrate. In an alternative, the heat slug may be embedded into the prepregnated material, not shown. Thermal via connections are made by copper layer 18 to the heat slug using lithography on the build-up layers, as shown in FIG. 4. Copper layer 18 also connects to copper layer 14, as shown.

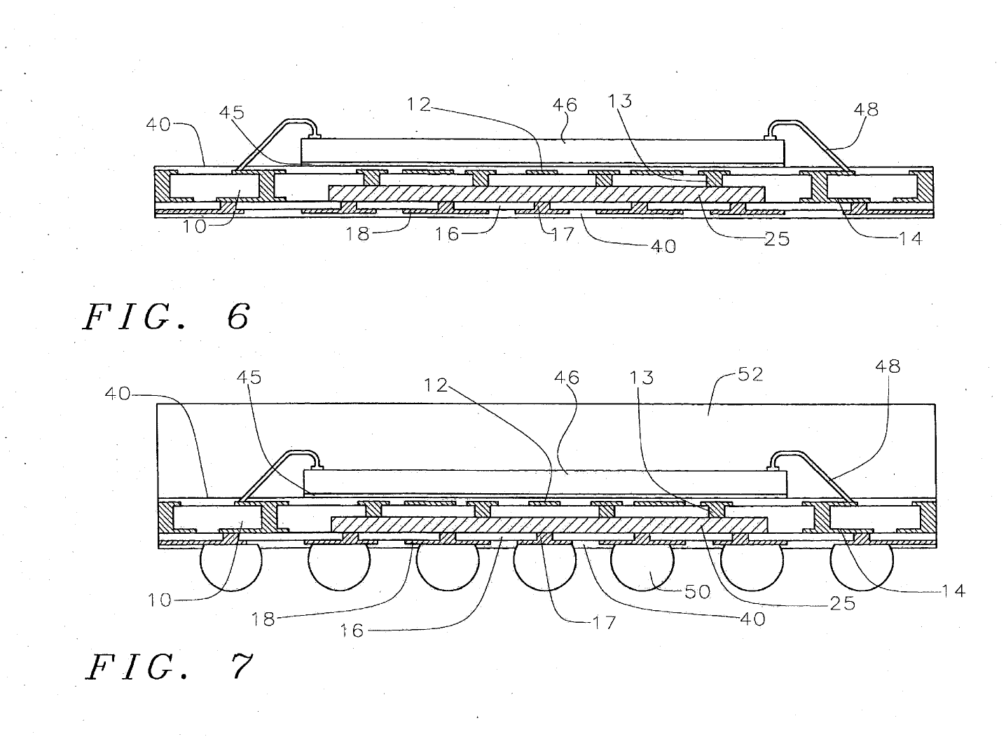

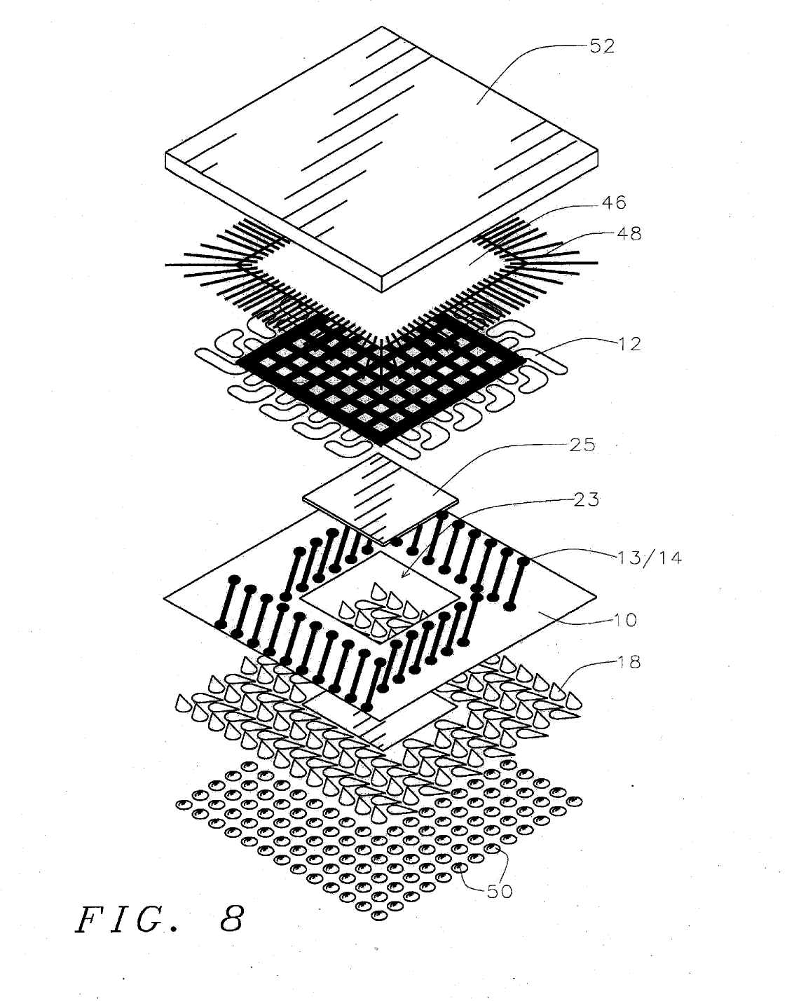

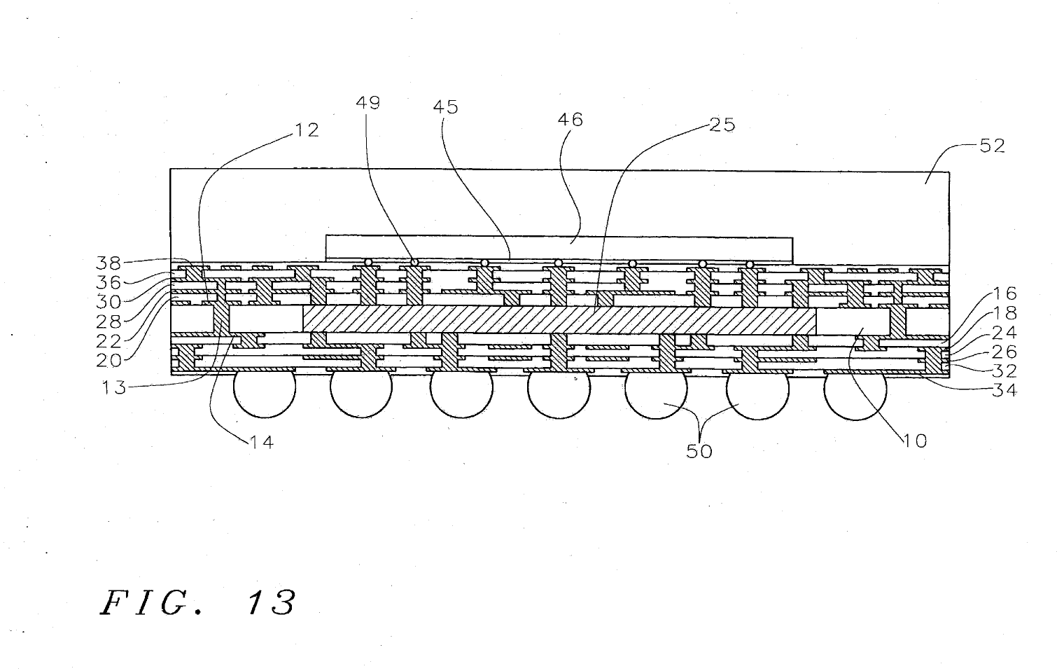

Now, in FIG. 5, a solder mask 40 is coated on the top and bottom of the build-up substrate. A die 46 is attached on top of the substrate using die attach material 45, such as Cu (copper), Au (gold), or CuPd (copper palladium), as shown in FIG. 6. Wire bonds 48 form wirebond connections between the die and metal layer 12. Alternatively, flip chip bumps 49 can be used in the case of FCCSP assemblies, as shown in FIG. 12.

The metal layers 12/14/17 are thermally connected, forming ground signal interconnects (traces, vias and planes). Ground planes are the metal layers that are internal to the substrates. These metal layers or planes are directly in contact with the heat slug; that is, the heat slug is linked to each of the ground metal layers (traces, planes and vias composing the ground net signals).

FIG. 7 shows molding compound 52 encapsulating the die 46. Solder balls 50 are attached to the bottom of the substrate. This completes the package.

The heat slug has no direct contact to the solder balls 50 or to the silicon die 46. All thermal connections or thermal paths are linked to the heat slug through the ground planes of all layers. On electronic packages, the die contains the components that generate heat. When power is inputted to the chip (or die) and the system turns on, heat is generated inside the chip. This heat will be dissipated throughout the package through the heat transfer process called conduction. With the help of the heat slug, a major percentage of heat can flow to the system printed circuit board (PCB), not shown. The PCB is a mounting board used by the end-customer and is not part of the electronic package.

FIG. 8 illustrates an exploded view of the layers in FIG. 7. Solder balls 50 are shown at the bottom of FIG. 8. Next, is the bottom metal substrate layer 18. On top of layer 18 is the core material 10. Inner metal layer 14 and via connections 13 are also within this layer. The heat slug 25 is embedded in the core substrate 10 as shown by the cavity 23 in FIG. 8. Substrate top metal layer 12 is shown above the heat slug 25 and is connected to the inner metal layer 14 by via connections 13, shown in FIG. 3. Silicon die 46 and bond wires 48 are shown in the next to top layer in FIG. 8. Mold compound 52 is shown as the top layer.

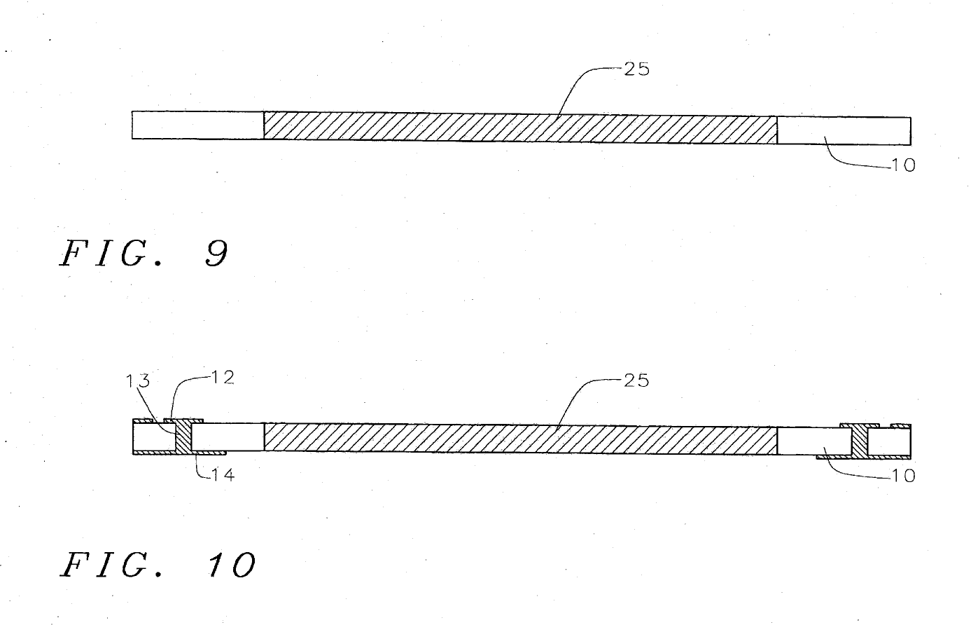

The embedded heat slug of the present disclosure is applicable to a substrate having three or more layers. Referring now more particularly to FIGS. 9-13, a preferred method of embedding a heat slug within an eight-layered substrate will be described. FIG. 9 illustrates a core substrate 10 into which a cavity has been drilled. In this example, the cavity extends through the entire depth of the core substrate. Heat slug 25 is embedded in the cavity in the substrate core layer.

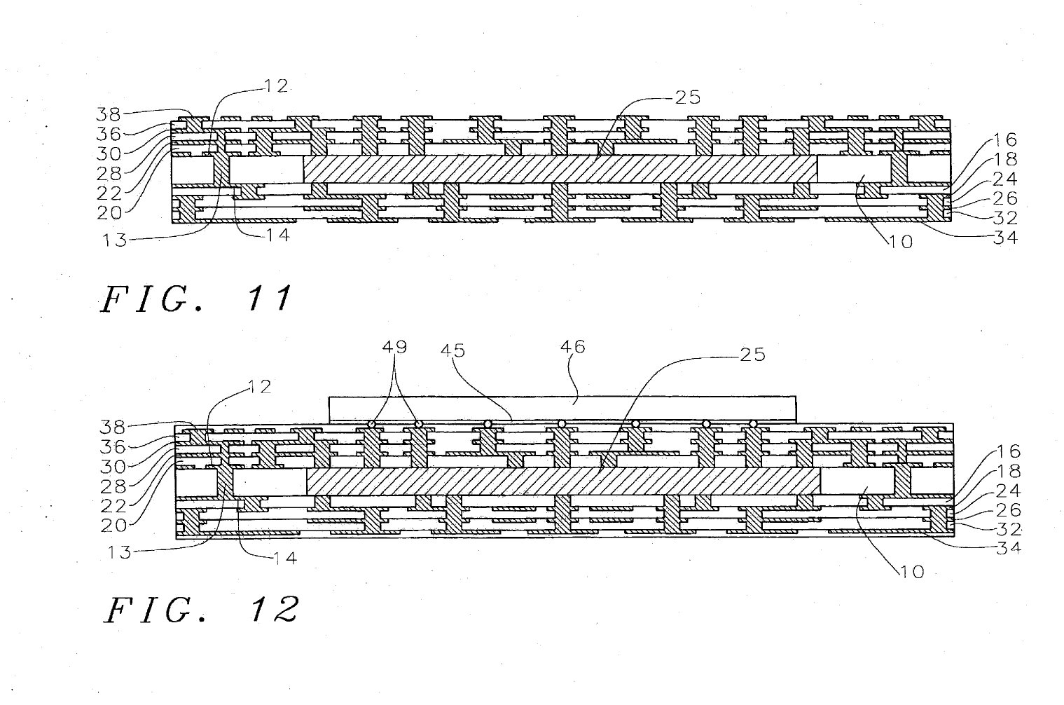

Now, a first metal layer 12 and second metal layer 14 are formed on the top and bottom of the core material 10, respectively. Thermal via connections 13 are formed in the first metal layer to connect to the heat slug 25 and to connect metal 12 and metal 14, as shown in FIG. 10. Succeeding build up layers will then be laminated on top and/or bottom of the core substrate.

FIG. 11 shows a first build-up substrate comprising dielectric prepregnated material 16 laminated on the bottom of the core substrate. Thermal via connections are made by copper layer 17 to the heat slug using lithography on the build-up layers, as shown in FIG. 11. Copper layer 17 also connects to copper layer 14, as shown. Additional build-up layers are laminated onto the top and/or bottom of the build-up substrate and lithography and copper-filled via is used to make the electrical and thermal connections to the heat slug and between metal layers. FIG. 11 illustrates prepregnated layers 16, 24, and 32 on the bottom of the substrate and metal layers 18, 26, and 34, on and through those layers, respectively. On the top of the substrate, prepregnated layers 20, 28, and 36 are successively laminated and connections made using copper layers 22, 30, and 38, respectively. This example shows eight metal layers. It will be understood that any number of metal layers, three or more could be used.

Now, in FIG. 12, a solder mask 40 is coated on the top and bottom of the build-up substrate. A die 46 is attached on top of the substrate using die attach material 45, such as Cu (copper), Au (gold), or CuPd (copper palladium). Flip chip bumps 49 make connections between the die and the metal layer 12. Alternatively, wire bonds 48 can be used, as shown in FIG. 5. All the metal layers are thermally connected, forming ground signal interconnects (traces, vias and planes).

FIG. 13 shows molding compound 52 encapsulating the die 46. Solder balls 50 are attached to the bottom of the substrate. This completes the package.

The method and device of the present disclosure allow electronic packages to be thinner, which is advantageous for constructing smaller applications, such as mobile phones, for example. Another advantage is that electronic packages of the present disclosure can be allowed to dissipate more power than previous devices, which can be used in high performance chips.

A Finite Differential Modeling (FDM) technique was employed to assess thermal performance of the electronic package of the present disclosure. The simulation suggests that more heat is absorbed by the embedded heat slug of the present disclosure and that the heat dissipates quickly from the package going to the printed circuit board. Furthermore, copper traces can be routed away from the embedded heat slug using multilayer substrates making the design flexible.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. An electronic package comprising:
a substrate having three or more metal layers, comprising a dielectric core layer, a metal layer within said dielectric core layer thermally connected to at least one metal layer on top of said dielectric core layer and to at least one metal layer on bottom of said dielectric core layer;
a die attached above said substrate; and
a heat slug embedded within said dielectric layer wherein said heat slug has no direct contact to said die and wherein said heat slug is thermally connected to each of said metal layers.

2. The package according to claim 1 wherein said substrate is selected from the group containing a ball grid array substrate (BGA), a Flip Chip Chip Scale Package (FC-CSP), a Land Grid Array (LGA), and a System in Package (SIP).

3. The package according to claim 1 wherein said substrate is a build-up substrate comprising a prepregnated dielectric material layer laminated on one of said metal layers on top or bottom of said dielectric layer and a metal layer on said prepregnated material and connecting to an underlying metal layer and further comprising prepregnated dielectric material laminated on a metal layer on an underlying prepregnated material layer.

4. The package according to claim 3 wherein said heat slug is embedded within said dielectric core layer or within said prepregnated dielectric material.

5. The package according to claim 1 further comprising wire bonds connecting said die to a topmost metal layer of said substrate.

6. The package according to claim 1 further comprising flip chip bumps connecting said die to a topmost metal layer of said substrate.

7. The package according to claim 1 wherein heat from said die is dissipated through said heat slug and said thermally connected metal layers.

8. A method of fabricating an electronic package comprising:
providing a substrate having three or more layers, comprising a dielectric layer and a metal layer within said dielectric layer thermally connected to at least one metal layer on top of said dielectric layer and to at least one metal layer on bottom of said dielectric layer;
embedding a heat slug completely within said dielectric layer;
attaching a die above said substrate; and
linking thermal paths to said heat slug through all of said metal layers.

9. The method according to claim 8 wherein said substrate is selected from the group containing a ball grid array substrate (BGA), a Flip Chip Chip Scale Package (FC-CSP), a Land Grid Array (LGA), and a System in Package (SIP).

10. The method according to claim 8 further comprising forming a build-up substrate comprising:
laminating a prepregnated dielectric material layer on one of said metal layers on top or bottom of said dielectric layer;
forming a metal layer on said prepregnated material and thermally connecting it to an underlying metal layer; and
laminating a second prepregnated dielectric material on a metal layer on an underlying prepregnated material layer; and
forming a second metal layer on said second prepregnated material and connecting it to an underlying metal layer; and
continuing this process until a desired number of substrate layers are formed.

11. The method according to claim 10 comprising embedding said heat slug within said dielectric core layer or within said prepregnated dielectric material.

12. The method according to claim 8 further comprising connecting said die to a topmost metal layer of said substrate using wire bonds.

13. The method according to claim 8 further comprising connecting said die to a topmost metal layer of said substrate using flip chip bumps.

14. The method according to claim 8 wherein heat from said die is dissipated through said heat slug and said thermal paths.

15. A method of fabricating an electronic package comprising:
providing a substrate having three or more layers, comprising a dielectric layer and a metal layer within said dielectric layer thermally connected to at least one metal layer on top of said dielectric layer and to at least one metal layer on bottom of said dielectric layer wherein said thermally connected metal layers form ground signal interconnects;
embedding a heat slug completely within said dielectric layer;
attaching a die above said substrate wherein said die has no direct connection to said heat slug; and
linking thermal paths to said heat slug through said ground signal interconnects.

16. The method according to claim 15 wherein said substrate is selected from the group containing a ball grid array substrate (BGA), a Flip Chip Chip Scale Package (FC-CSP), a Land Grid Array (LGA), and a System in Package (SIP).

17. The method according to claim 15 further comprising forming a build-up substrate comprising:
laminating a prepregnated dielectric material layer on one of said metal layers on top or bottom of said dielectric layer;
forming a metal layer on said prepregnated material and connecting it to an underlying metal layer; and
laminating a second prepregnated dielectric material on a metal layer on an underlying prepregnated material layer; and
forming a second metal layer on said second prepregnated material and connecting it to an underlying metal layer; and
continuing this process until a desired number of substrate layers are formed.

18. The package according to claim 17 wherein said heat slug is embedded within said dielectric core layer or within said prepregnated dielectric material.

19. The method according to claim 15 further comprising connecting said die to a topmost metal layer of said substrate using wire bonds or flip chip bumps.

20. The method according to claim 15 wherein heat from said die is dissipated through said heat slug and said thermal paths.
